(19) United States
(12) Patent Application Publication
(10) Pub. No.: US 2010/0258530 A1
(43) Pub. Date: Oct. 14, 2010

(54) SUBSTRATE PROCESSING APPARATUS AND PRODUCING METHOD OF DEVICE

(75) Inventors: Kazuyuki TOYODA, Toyaina-shi (JP); Nobuhito Shima, Tomaya-ken (JP); Nobuo Ishimaru, Takaoka-Shi (JP); Yoshikazu Konno, Toyama-shi (JP); Motonari Takebayashi, Takaoka-shi (JP); Takaaki Noda, Toyama-shi (JP); Norikazu Mizuno, Toyama-city (JP)

Correspondence Address: BIRCH STEWART KOLASCH & BIRCH, PO BOX 747, FALLS CHURCH, VA, 22040-0747, US

(73) Assignee: Hitachi Kokusai Electric Inc.

(21) Appl. No.: 12/820,893

(22) Filed: Jun. 22, 2010

Related U.S. Application Data
(62) Division of application No. 10/547,320, filed on Jul. 5, 2006.

(30) Foreign Application Priority Data
Mar. 4, 2003 (JP) 2003-056772

(51) Int. Cl. C23F 1/00; C23F 1/08; B05C 11/00; C23C 16/52

(52) U.S. Cl. 216/84; 156/345.27; 118/712; 427/8

(57) ABSTRACT

A substrate processor enables realization of a proper process by combining advantages of a remote plasma and a plasma generated in an entire processing chamber. The substrate processor includes a conductive member (10) which is installed surrounding a processing space (1) and grounded to the earth and a pair of electrodes (4) installed inside the conductive member (10). A primary coil of an insulating transformer (7) is connected to a high-frequency power supply unit (14) and a secondary coil is connected to the electrodes (4). A switch (13) is connected to the connection line connecting the secondary coil to the electrodes (4). By setting up/cutting off the connection of the line to the earth with use of the switch (13), the region where the plasma is generated in the processing space (1) can be changed.

This application is a Divisional of co-pending application Ser. No. 10/547,320 filed on Sep. 1, 2005, which is a National Phase of PCT/JP04/02735 filed on Mar. 4, 2004, which claims priority to Japanese Application No. 2003-056772 filed in Japan, on Mar. 4, 2003. The entire content of all of the above applications is hereby expressly incorporated by reference.

### TECHNICAL FIELD

The present invention relates to a substrate processing apparatus and a producing method of a device, and more particularly, to a substrate processing apparatus which carries out processing such as forming a thin film on a substrate such as a wafer, impurity diffusion and etching, and to a producing method of a device using the substrate processing apparatus.

### BACKGROUND ART

Some substrate processing apparatuses such as semiconductor producing apparatuses activate processing gas such as raw material gas used for processing a substrate, and carries out processing such as film formation on the substrate.

If plasma is produced by discharging, electrically neutral radical (active species) having relatively long lifetime and small energy, and charged ion having relatively short lifetime and great energy are generated at the same time. A remote plasma type substrate processing apparatus produces plasma only in a buffer chamber (discharge chamber) isolated from a processing chamber, and supplies only neutral radical having relatively long lifetime to a substrate and processes the substrate (at that time, most of ions having short lifetime are deactivated). However, if high frequency electric power (RF electric power) to be supplied to an electrode is increased to enhance the processing ability with respect to the substrate, plasma is produced not only in the buffer chamber (discharge chamber) but also in entire region in the processing chamber. This is because that if high frequency electric power to be supplied to an electrode is increased, high frequency electric field (RF electric field) generated between the electrode and conductive members around the processing chamber is increased and thus, discharge is caused not only in the buffer chamber but also in the entire region in the processing chamber and as a result, plasma is produced over the entire region in the processing chamber. If plasma is produced in the vicinity of a substrate, not only the neutral radical (active species) but also high energy ion reach the substrate. The high energy ion charges up a circuit element which has already been produced on the substrate, the high energy ion destroys the circuit element, and if high energy plasma collides against the substrate, the substrate is physically damaged, and this because a cause of hindrance of excellent substrate processing.

Therefore, it is a main object of the present invention to provide a substrate processing apparatus capable of processing a substrate in a state in which plasma is not produced in the vicinity of the substrate, and to provide a producing method of a device using the substrate processing apparatus.

It is another main object of the invention to provide a substrate processing apparatus capable of increasing processing speed of a substrate.

### DISCLOSURE OF THE INVENTION

According to a first aspect of the present invention, there is provided a substrate processing apparatus, comprising:

a processing space which provides a space where a substrate or substrates are processed;

a conductive member which is provided such as to surround said processing space from outside and which is grounded;

a pair of electrodes provided inside of said conductive member;

a high frequency power source;

an isolation transformer having a primary side coil which is electrically connected to said high frequency power source and a secondary side coil which is electrically connected to said electrodes;

a switch which is connected to one of connection lines which respectively electrically connects said secondary side coil of said isolation transformer with said pair of electrodes and which switches between connection and disconnection of said one of said connection lines to said ground; and

a control member which controls operation of said switch to switch between a state in which a plasma generation region in said processing space is a region where said substrate or said substrates are not placed and a state in which said plasma generation region in said processing space is a region where said substrate or said substrates are placed.

According to a second aspect of the present invention, there is provided a device producing method which produces a device using the above-mentioned substrate processing apparatus.

According to a third aspect of the present invention, there is provided a substrate processing apparatus, comprising:

a processing space which provides a space where a substrate or substrates are processed;

a conductive member which is provided such as to surround said processing space from outside and which is grounded;

a pair of electrodes provided inside of said conductive member and disposed in a region where said substrate or said substrates are not placed between said pair of electrodes; and

a high frequency power source which applies high frequency to said electrodes, wherein
when said substrate or said substrates are subjected to a desired processing, plasma is generated by said electrodes and said conductive member to generate plasma in a region where said substrate or said substrates in said processing space are placed.

According to a fourth aspect of the present invention, there is provided a substrate processing apparatus, comprising:

a processing chamber which processes a substrate or substrates;

a pair of electrodes which generate plasma;

a high frequency power source;

an isolation transformer having a primary side coil which is electrically connected to said high frequency power source and a secondary side coil which is electrically connected to said electrodes; and

a thermocouple mounted on said isolation transformer.

### BRIEF DESCRIPTION OF THE FIGURES IN THE DRAWINGS

FIG. 1 is a schematic transversal sectional view for explaining a processing furnace of a vertical decompression CVD apparatus according to a first embodiment of the present invention.

FIG. 2 is a schematic longitudinal sectional view for explaining the processing furnace of the vertical decompression CVD apparatus according to the first embodiment of the present invention.

FIG. 3 is a schematic transversal sectional view for explaining a processing furnace of a vertical decompression CVD apparatus according to a second embodiment of the present invention.

FIG. 4 is a schematic longitudinal sectional view for explaining the processing furnace of the vertical decompression CVD apparatus according to the second embodiment of the present invention.

FIG. 5 is a schematic transversal sectional view for explaining a processing furnace of a vertical decompression CVD apparatus according to a second embodiment of the present invention.

FIG. 6 is a schematic longitudinal sectional view for explaining the processing furnace of the vertical decompression CVD apparatus according to the second embodiment of the present invention.

FIG. 7 is a diagram for explaining one example of time sequence of processing gas when substrates are processed using the vertical decompression CVD apparatus according to the second embodiment of the present invention.

FIG. 8 is a diagram for explaining film thickness distribution when films are respectively formed by entire plasma and remote plasma using the vertical decompression CVD apparatus of the second embodiment of the present invention.

FIG. 9 is a diagram for explaining dependence of film forming speed on NH₃-Flowtime when films are respectively formed by entire plasma and remote plasma using the vertical decompression CVD apparatus of the second embodiment of present the invention.

FIG. 10 is a schematic diagram for explaining one example of a plasma generating circuit used in the processing furnace of the vertical decompression CVD apparatus according to a third embodiment of the present invention.

FIG. 11 is a schematic diagram for explaining another example of the plasma generating circuit used in the processing furnace of the vertical decompression CVD apparatus according to the third embodiment of the present invention.

FIG. 12 is a schematic diagram used for explaining still another example of the plasma generating circuit used in the processing furnace of the vertical decompression CVD apparatus according to the third embodiment of the present invention.

FIG. 13 is a schematic transversal sectional view for explaining a processing furnace of a vertical decompression CVD apparatus for comparison

FIG. 14 is a schematic longitudinal sectional view for explaining the processing furnace of the vertical decompression CVD apparatus for comparison.

### PREFERABLE MODE FOR CARRYING OUT THE INVENTION

According to a preferable embodiment of the present invention, there is provided a substrate processing apparatus, comprising:

a processing space which provides a space where a substrate or substrates are processed;

a conductive member which is provided such as to surround said processing space from outside and which is grounded;

a pair of electrodes provided inside of said conductive member;

a high frequency power source;

an isolation transformer having a primary side coil which is electrically connected to said high frequency power source and a secondary side coil which is electrically connected to said electrodes;

a switch which is connected to one of connection lines which respectively electrically connects said secondary side coil of said isolation transformer with said pair of electrodes and which switches between connection and disconnection of said one of said connection lines to said ground; and

a control member which controls operation of said switch to switch between a state in which a plasma generation region in said processing space is a region where said substrate or said substrates are not placed and a state in which said plasma generation region in said processing space is a region where said substrate or said substrates are placed.

By providing the isolation transformer between the electrodes and the high frequency power source, the electrodes are not connected to the ground, and the electrodes are insulated from the conductive member around the processing space. Therefore, even if high frequency electric power is supplied between the electrodes and plasma is generated, variation in potential in the electrodes does not generate a potential difference with respect to the conductive member. Therefore, discharge between the electrodes and the conductive member is prevented, and plasma is prevented from being generated in the entire processing space. As a result, plasma is prevented from being generated in the vicinity of the substrate or substrates by separating the substrate or the substrates from the electrodes.

Moreover, by controlling the operation of the switch by the control unit, connection and disconnection between the electrodes and the ground can be switched. Therefore, it is possible to easily switch the plasma generation locations, i.e., a location only in the buffer chamber or the like where the substrate or the substrates are not placed and a location in the buffer chamber and the entire region in the processing chamber.

Furthermore, since the conductive member is provided such as to surround the processing space from outside, it is possible to prevent high frequency electric power when plasma is produced from leaking outside. When the electrodes are connected to the ground by the switch, plasma can easily and equally be generated in the processing space, and this is effective when dry cleaning is carried out in the processing space.

Further, if ferrite core is used as a core of the isolation transformer, since the ferrite has higher permeability and saturation flux density in the high frequency band, and since specific resistance is greater as compared with a metal magnetic material, RF electric power can be supplied efficiently and stably even if the transformer is small in size.

According to a preferable another embodiment of the present invention, there is provided a substrate processing apparatus, comprising:

a processing space which provides a space where a substrate or substrates are processed;

a conductive member which is provided such as to surround said processing space from outside and which is grounded;

a pair of electrodes provided inside of said conductive member and disposed in a region where said substrate or said substrates are not placed between said pair of electrodes; and

a high frequency power source which applies high frequency to said electrodes, wherein
when said substrate or said substrates are subjected to a desired processing, plasma is generated by said electrodes and said conductive member to generate plasma in a region where said substrate or said substrates in said processing space are placed.

With this apparatus, a substrate processing speed can be improved.

According to a preferable still another embodiment of the present invention, there is provided a substrate processing apparatus, comprising:

a processing chamber which processes a substrate or substrates;

a pair of electrodes which generate plasma;

a high frequency power source;

an isolation transformer having a primary side coil which is electrically connected to said high frequency power source and a secondary side coil which is electrically connected to said electrodes; and

a thermocouple mounted on said isolation transformer.

The temperature of the isolation transformer can appropriately be measured by the thermocouple, and it is possible to avoid a case in which the temperature of the isolation transformer rises during the processing of the substrate or the substrates, and the substrate processing apparatus is brought into a dangerous state.

Next, preferable embodiments of the present invention will be explained in more detail with reference to the drawings.

One example of a substrate processing apparatus to which the present invention is applied is a vertical decompression CVD apparatus. Although it is not illustrated in the drawings, the vertical decompression CVD apparatus is provided at its front surface with a carry in/out unit which carries a pod accommodating a plurality of substrates into and out from the apparatus. Although it is not illustrated in the drawings, a pod shelf which holds the plurality of pods, a pod stage which is located below the pod shelf and on which the pods are placed, a pod transfer machine which transfers the pods between the carry in/out unit, the pod shelf and the pod shelf, and the like are provided on a front side in the apparatus. Although it is not illustrated in the drawings, on a rear side in the apparatus, there are provided a boat which holds multi-stacked substrates, a wafer loader which transfers substrates in the pod placed on the pod stage to a boat of a substrate holder, a boat elevator which inserts the boat into the processing furnace and the like. The apparatus is provided at its rear upper portion with a processing furnace 24 which processes the substrates.

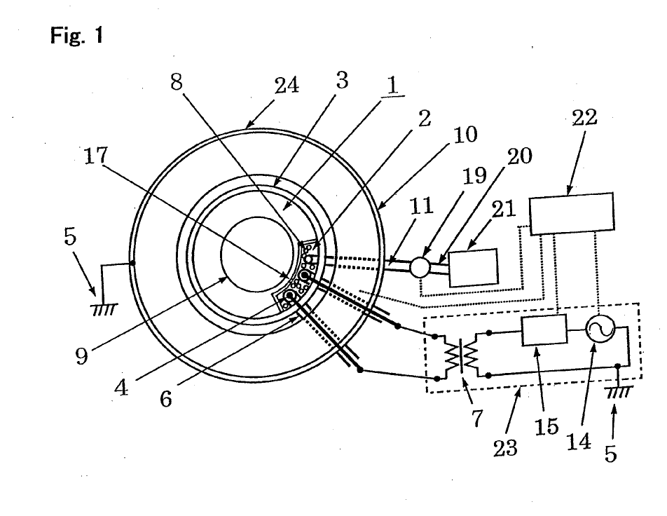

Next, the processing furnace of the vertical decompression CVD apparatus according to an embodiment to which the present invention is applied will be explained with reference to FIGS. 1 to 6.

The vertical decompression CVD apparatus includes a processing space which provides a space in which a substrate is processed, a conductive member which is provided such as to surround the processing space from outside and which is grounded, a pair of electrodes provided inside of the conductive member, a high frequency power source, an isolation transformer having a primary side coil which is electrically connected to the high frequency power source and a secondary side coil which is electrically connected to the electrodes, a switch which is connected to one of connection lines which are electrically connected to the secondary side coil of the isolation transformer and the pair of electrodes and which switches between connection and disconnection between the ground and one of the connection line, and a control unit which controls the operation of the switch and which switches between a state in which a plasma generation region in the processing space is a region where the substrate is not placed and a state in which the plasma generation region in the processing space is a region where the substrate is placed.

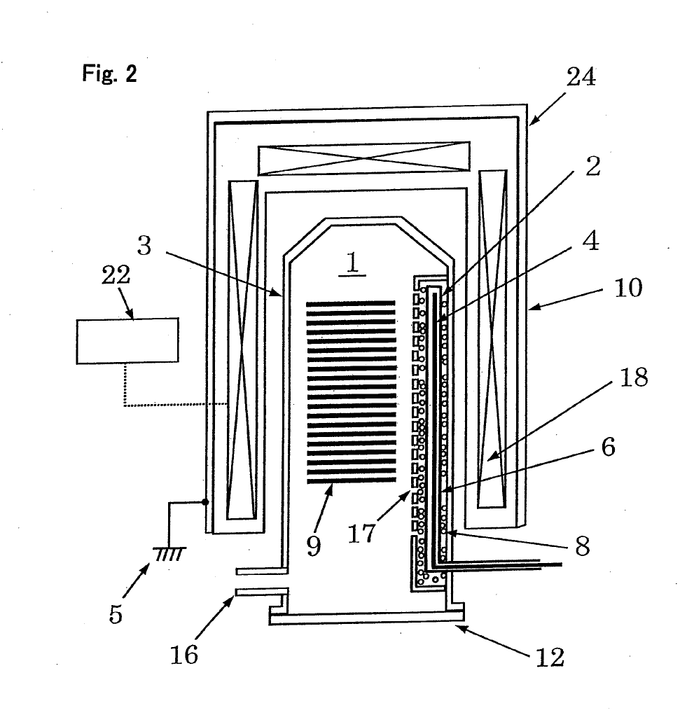

FIGS. 1 and 2 are schematic transverse sectional view and schematic vertical sectional view of the processing furnace 24 of the decompression CVD apparatus.

A processing chamber 1 is of an air-tight structure comprising a substantially cylindrical quartz reaction tube 3 having an opened lower end, and a seal flange 12 which closes the lower end. The reaction tube 3 is provided at its inner wall side portion with a quartz buffer chamber 2. A pair of electrodes 4 which produces plasma 8 is provided in the buffer chamber 2 in a state in which the electrodes 4 are covered with electrode protection tubes 6. Discharge can be generated between the electrodes 4 by high frequency electric power supplied to a later-described plasma generating circuit 23. A heater 18 comprising a heater wire and a heat insulation member (not shown) is provided outside of the reaction tube 3. Substrates 9 in the processing chamber 1 and atmosphere in the processing chamber 1 can be heated to a desired temperature by a signal from the control unit 22.

The reaction tube 3 is provided at its lower portion with an exhaust port 16 through which gas is exhausted from the processing chamber 1, and a gas introduction port 11 through which desired gas is introduced into the buffer chamber 2. A gas introduction tube 20 is connected to the gas introduction port 11. The gas introduction port 11 is connected to a gas supply source 21 through a valve 19 which is opened and closed by a signal from a control unit 22. Processing gas introduced from the gas introduction port 11 is brought into plasma state by discharge generated in the decompressed buffer chamber 2. The processing gas activated by the plasma is supplied into the processing chamber 1 through a small hole 17 of the buffer chamber 2, and the substrates in the processing chamber 1 are subjected to desired processing. An apparatus which produces plasma in a space where substrates outside the processing chamber are not placed, and which supplies the plasma-activated processing gas to the processing chamber to carry out the substrate processing is called a remote plasma type substrate processing apparatus. In order to prevent the high frequency electric power generated by the electrodes 4 from leaking outside of the apparatus while plasma 8 is produced in the buffer chamber 2, a conductive grounded cover 10 is provided outside of the reaction tube 3.

The plasma generating circuit 23 includes an isolation transformer 7, the high frequency power source 14, a matching machine 15 and a pair of electrodes which are connected to the control unit 22. The high frequency electric power (RF electric power) is supplied from the high frequency power source 14 by a signal from the control unit 22, a high frequency power source and plasma impedance are matched with each other and then, the high frequency electric power is supplied to the electrodes 4 through the isolation transformer 7. By providing the isolation transformer 7 between the electrodes 4 and the high frequency power source 14, the electrodes 4 are not connected to the ground 5, and the electrodes 4 are insulated from the conductive members around the processing chamber 1. Therefore, even if the high frequency electric power is supplied between the electrodes 4 to discharge and plasma 8 is generated, variation in potential in the electrodes 4 do not generate a potential difference with respect to the conductive member. Therefore, generation of plasma by discharge between the electrodes 4 and the conductive member is prevented, and plasma is prevented from being produced in the entire region in the processing chamber 1.

A doughnut-shaped ferrite core is used for the isolation transformer 7. Ferrite has high permeability and saturation flux density in a high frequency band, and has higher specific resistance as compared with a metal magnetic material. Therefore, if ferrite is used for the core of the isolation transformer 7, it is possible to efficiently and stably supply power source even if the transformer is small in size.

Next, the operation of the vertical decompression CVD apparatus to which the present invention is applied will be explained. If a pod in which a plurality of substrates are accommodated is carried into the apparatus by a carry in/out unit, the pod is transferred to a pod shelf (not shown) by a pod transfer machine and is stored there. The pod transferred to the pod shelf is transferred to a pod stage by the pod transfer machine, and moved on a boat (not shown) by a substrate loader. The boat which holds the multi-stacked substrates is inserted into the processing furnace 24 by an elevator, a lower portion of a reaction tube is tightly closed by the seal flange 12 located at a lower portion of the boat, thereby forming the processing chamber 1.

Electric power is supplied to the heater 18 by a signal from the control unit 22, and constituent elements in the processing chamber 1 such as the substrates 9, the reaction tube 3 and the boat (not shown), as well as atmosphere in the processing chamber 1 are heated to a predetermined temperature. When these elements and the like are heated by the heater 18, gas is exhausted from the processing chamber 1 through the exhaust port 16 by a pump (not shown) at the same time. If the pressure in the processing chamber 1 reaches a predetermined value, and if the temperature of the substrates 9 reaches a predetermined value, reaction gas is introduced into the processing chamber 1 from the gas introduction port 11, and the pressure in the processing chamber 1 is maintained at a predetermined value by a pressure adjusting mechanism (not shown).

After the pressure in the processing chamber 1 reached the predetermined value, high frequency electric power is supplied to the electrodes 4 from the plasma generating circuit 23 by a signal from the control unit 22, and plasma 8 is produced in the buffer chamber 2. At that time, the electrodes 4 are not connected to the ground and are insulated from the conductive members around the processing chamber 1. Therefore, even if high frequency electric power is supplied between the electrodes 4 to discharge and plasma is generated, plasma is not generated in the entire region in the processing chamber 1.

The plasma-excited and activated processing gas is supplied to the substrates in the processing chamber 1 from the small hole 17, and the substrates 9 are subjected to desired processing. In actual case, when high voltage is applied to the isolation transformer, insulation of the isolation transformer breaks down, the interior of the isolation transformer is brought into conduction and as a result, there is an adverse possibility that discharge is generated between the electrodes and the conductive member. Therefore, in an experiment, we created nitrogen gas atmosphere of 133 [Pa] in the processing chamber and supplied high frequency electric power to the electrodes 4 from the plasma generating circuit 22, and we confirmed that discharge was not generated in the processing chamber up to about 800 [W]. Thus, it is considered that plasma excitation of processing gas is not generated in the processing chamber 1 up to about 800 [W], and plasma excitation of the processing gas in the processing chamber is not generated with electric power of about 400 [W].

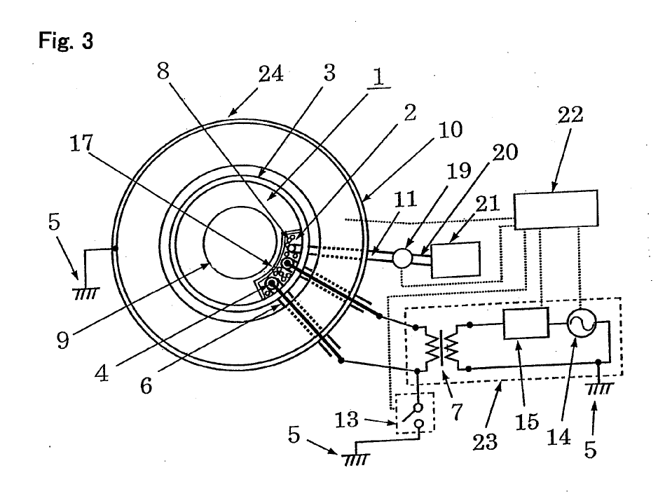

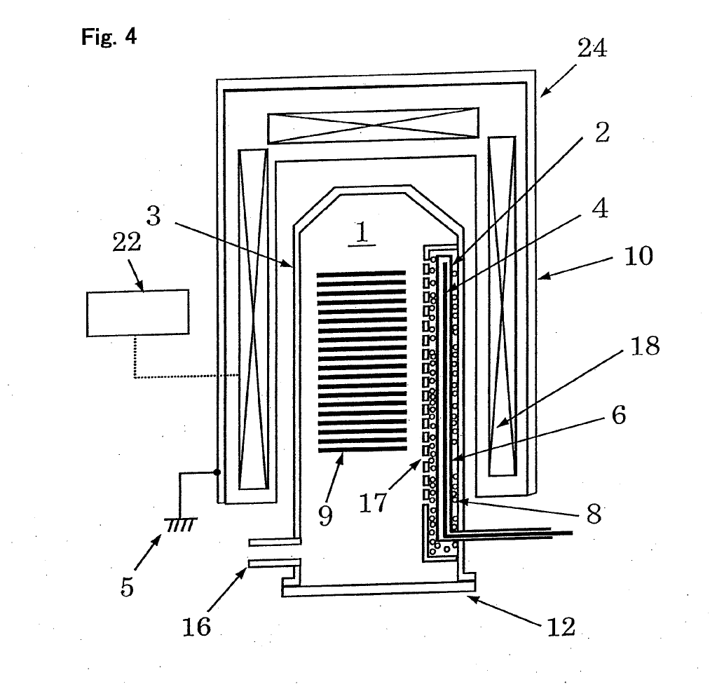

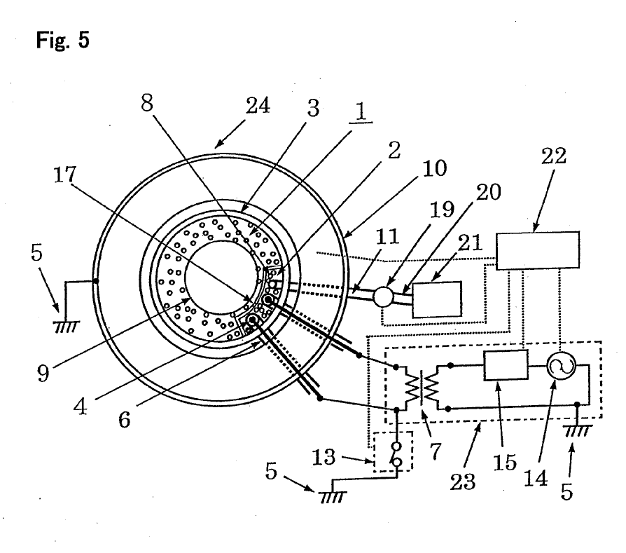

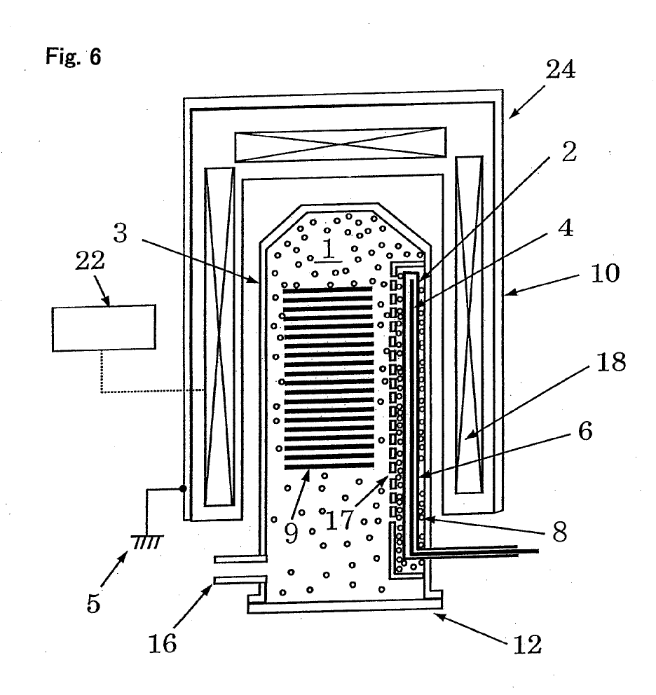

FIGS. 3 and 5 are schematic transverse sectional views and FIGS. 4 and 6 are schematic vertical sectional views of the processing furnace 24 of the vertical decompression CVD apparatus of a second embodiment of the present invention.

The second embodiment shown in FIGS. 3 to 6 is different from the first embodiment shown in FIGS. 1 and 2 in that one end of a supply line connected to the electrodes 4 of the isolation transformer 7 is connected to the ground 5, and the control unit 22 controls the opening and closing operation of the switch 13. The switch 13 may not be switched by the control unit 22 and may be switched manually.

FIGS. 3 and 4 show a state in which the switch 13 is opened, the electrodes 4 are insulated from the conductive members (e.g., the seal flange 12, the heater wire, the cover 10 and the like) around the processing chamber 1, and plasma 8 is produced only in the buffer chamber 2. FIGS. 5 and 6 show a state in which the electrodes 4 are connected to the conductive members around the processing chamber 1 through the ground 5, and plasma 8 is produced not only in the buffer chamber 2 but also in the entire region in the processing chamber. Since the connection and disconnection between the electrodes 4 and the ground 5 are switched using the switch 13, it is possible to easily switch the plasma generation locations, i.e., a location only in the buffer chamber 2 and a location in the buffer chamber and the entire region in the processing chamber.

Such a switching of the plasma generating locations is effective when the processing chamber 1 is cleaned using plasma. In the CVD apparatus, since reaction by-product adhered to the inside of the processing chamber 1 at the time of processing of substrates is periodically removed, cleaning gas is supplied into the processing chamber 1 and dry cleaning is carried out. At that time, the cleaning can be carried out efficiently if plasma is utilized. Thus, when substrate processing is carried out, the switch 13 is opened, processing is carried out using remote plasma (local plasma) in which plasma is generated only in the buffer chamber 2 (space where substrates are not placed), and when the processing chamber 1 is dry-cleaned, cleaning processing is carried out in a plasma mode (entire plasma) in which the switch 13 is closed and plasma is allowed to be generated in the entire processing chamber 1. When plasma is allowed to be generated in the entire processing chamber, since a region where the plasma is allowed to be generated is large, high frequency electric power is increased to about 800 W that is higher than that of the case of local plasma.

When plasma is generated in the entire processing furnace, since plasma exists in the entire processing chamber in a state in which cleaning gas is activated (energy is high), cleaning efficiency can be enhanced.

A secondary switch 13 of the isolation transformer 7 is connected to the ground before flowing the cleaning gas. The cleaning is started after the substrate processing is completed, the substrates 9 are carried out from the processing chamber 1 and empty boat (not shown) is inserted into the processing chamber 1.

If the substrate processing is carried out using the substrate processing apparatus having the above-described features, a semiconductor apparatus having small substrate damage can be produced.

Next, an example in which the local plasma and the entire plasma are properly used in the substrate processing using such an apparatus will be explained.

The local plasma electrically supplies only neutral active species when wafers are processed. For example, in producing process of a semiconductor integrated circuit, the local plasma is used for forming a transistor gate spacer (e.g., nitride film) of a DRAM comprising an integrated circuit, and for forming an ONO film (laminated film of O=oxide film and N=nitride film) of a gate oxide film portion of a flash memory.

It is known that film quality is deteriorated due to high energy charged particle in plasma, but its mechanism is varied case by case and is not clearly known.

If plasma is spread over the entire reaction chamber, impurities which adversely affects the process may be mixed from reaction chamber member (e.g., metal and seal constituting the reaction chamber) in some cases, and this may deteriorate the film quality.

Thus, plasma is made of material (quartz or the like) having few impurities (=buffer chamber (discharge chamber)), and a remote plasma process in which only electrically neutral active species produced in the discharge chamber provided at a location away from a substrate to be processed is supplied to the substrate to be processed is used.

If plasma is spread over the entire reaction chamber, since plasma exists in the vicinity of the substrate to be processed, active particles having short lifetime can also be supplied to the surface of the substrate to be processed. Therefore, the processing speed can be increased and throughput can be enhanced.

The entire plasma deteriorates the film quality (by high energy ion), mixes impurities into the film (=impurities mixing in the explanation of process using the above-described local plasma). Therefore, the entire plasma can be applied to process in which these problems are not so serious. For example, the entire plasma can be applied to bit line spacer (e.g., nitride film) in a wiring procedure.

Merits of the local plasma and the entire plasma can be combined with each other to realize an excellent process.

For example, in a transistor periphery process comprising an integrated circuit (e.g., nitride film), if initial film formation (several tens Å) is carried out using the local plasma and remaining film formation of several hundreds Å is carried out using the entire plasma, it is possible to realize a process having excellent device characteristics and high throughput (since a film state of an interface is important when a film is formed, if the initial film formation is carried out using the local plasma, a film having excellent quality can be formed with high throughput).

According to the present invention, if an RF feeder unit is provided with the isolation transformer and a secondary side thereof is insulated by means of the switch (switch is turned OFF), local plasma can be obtained. Since this switch can automatically be switched, if the local plasma is automatically switched to the entire plasma while the process proceeds, process having high throughput can be realized.

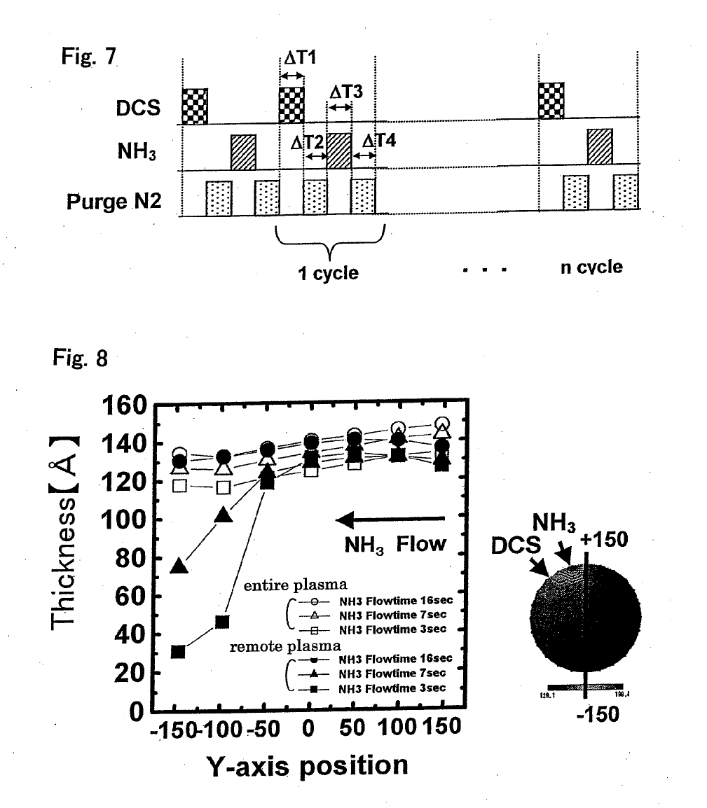

Next, the substrate processing using the substrate processing apparatus will be explained with reference to FIGS. 7 to 9. The substrate processing apparatus includes the processing space which provides a space in which a substrate is processed, the conductive member which is provided such as to surround the processing space from outside and which is grounded, a pair of electrodes provided inside of the conductive member and disposed in regions where no substrate is placed between the electrodes, and a high frequency power source which applies high frequency to the electrodes. When the substrate is subjected to desired processing, plasma is generated by the electrodes and the conductive member, and plasma is produced in a region where a substrate in the processing space is placed.

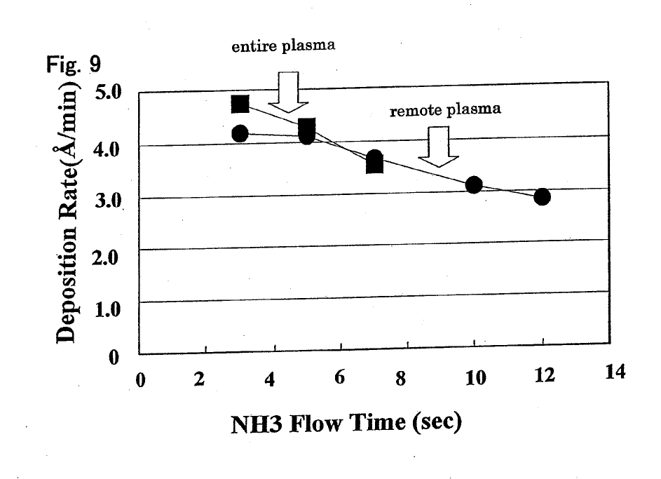

FIG. 7 is a diagram used for explaining one example of time sequence of processing gas when the substrate used in the state shown in FIGS. 5 and 6 is processed. FIG. 7 is also referred to as one example of time sequence of processing gas when the substrate used in the state shown in FIGS. 3 and 4 is processed. FIG. 8 is a diagram used for explaining film thickness distribution when films are formed by entire plasma (state shown in FIGS. 5 and 6) and remote plasma (state shown in FIGS. 3 and 4) using the vertical decompression CVD apparatus of the second embodiment of the invention. FIG. 9 is a diagram used for explaining the dependence of film forming speed on NH₃-Flowtime when films are formed by entire plasma (state shown in FIGS. 5 and 6) and remote plasma (state shown in FIGS. 3 and 4) using the vertical decompression CVD apparatus of the second embodiment of the invention.

Here, a producing method of device for forming a silicon nitride (SiN) on a substrate using dichlorsilane and ammonia as reaction gas by means of ALD (Atomic Layer Deposition) method.

To obtain a high quality SiN film, before ammonia is supplied to the processing chamber, the ammonia is activated using plasma in a space (buffer chamber) where substrates outside of the processing chamber are not placed and then, the ammonia is supplied to the processing chamber and the substrate processing is carried out. An apparatus which carries out the substrates is called a remote plasma type substrate processing apparatus.

If plasma is produced by the discharge, electrically neutral radical (active species) having relatively long lifetime and small energy, and charged ion having relatively short lifetime and great energy are generated at the same time. In the remote plasma type substrate processing apparatus, plasma is generated only in the buffer chamber and the charged ion does not reach the substrates. Therefore, it is possible to advantageously avoid a case in which a circuit element which has already been produced on a substrate is charged up, the circuit element is destroyed, plasma having high energy plasma collides against the substrate, and the substrate is physically damaged.

However, since there is a distance between the plasma generating location and the substrate, if time during which ammonia is activated with plasma in the buffer chamber and is supplied to the processing chamber is not relatively long, radical having high contributing degree with respect to film formation is deactivated, and a region where the film forming speed is extremely reduced locally is generated in the substrate. At that time, depositing or growing speed of film is also reduced. In order to enhance the substrate processing ability, it is necessary to form, as fast as possible, a film having equal thickness over the entire surface of the substrate.

Hence, plasma is generated in a state in which the switch 13 is closed (see FIGS. 5 and 6) using the vertical decompression CVD apparatus of the second embodiment of the invention, and the plasma generating range is spread not only to the buffer chamber 2 in the vicinity of the electrodes but also to the entire region in the processing chamber 1. Here, plasma which is spread over the entire region in the processing chamber 1 is called entire plasma hereinafter.

In the method for forming a thin film on a substrate by means of the ALD method (Atomic Layer Deposition) method using dichlorsilane and ammonia as the reaction gas using such a processing apparatus, it is possible to shorten the time required until ammonia is activated with plasma and the ammonia is supplied to the processing chamber by spreading plasma to a region in the vicinity of the substrate, and it is possible to largely enhance the consistency of the film thickness and the deposition speed.

Processing gas introduced from the gas introduction port 11 is brought into plasma state (entire plasma) by discharge generated in the decompressed buffer chamber 2 and processing chamber 1. The processing gas (ammonia gas) activated with entire plasma is supplied into the processing chamber 1 through the small hole 17 of the buffer chamber 2 or is activated with entire plasma in the vicinity of the substrate, and the substrates in the processing chamber 1 are subjected to desired processing. A gas introducing system of dichlorsilane is not illustrated in the drawings.

FIG. 7 shows time sequence of processing gas at the time of substrate processing. Here, dichlorsilane (DCS) and ammonia (NH₃) as processing gases are supplied from different systems into the reaction furnace for time ΔT1 and time ΔT3, respectively. One which is actually excited with plasma is NH₃, and this corresponds to ΔT3 in FIG. 3. There are N₂ purge time periods ΔT2 and ΔT4 between DCS supply and NH₃ supply. In the ALD method, time periods of ΔT1, ΔT2, ΔT3 and ΔT4 are added and the total time is defined as one cycle. In order to enhance the substrate processing ability, it is necessary to form a film having the equal thickness over the entire surface of the substrate as fast as possible, i.e., to reduce time (time of ΔT1, ΔT2, ΔT3 and ΔT4) required for one cycle as short as possible. In the present invention, it was found that time ΔT3 can be largely reduced if entire plasma is used.

FIG. 8 shows film thickness distribution of ALD-SiN film in a surface of a substrate while comparing entire plasma and remote plasma with each other. The entire plasma is obtained by generating plasma in a state in which the switch 13 is closed (see FIGS. 5 and 6) and by spreading the generation range of plasma not only to the buffer chamber 2 in the vicinity of the electrodes but also to the entire region in the processing chamber 1. The remote plasma is obtained by generating plasma in a state in which the switch 13 is opened (see FIGS. 3 and 4) and by limiting the plasma generation range only to the buffer chamber 2 in the vicinity of the electrodes. In the case of the remote plasma, it can be found that as the NH₃-Flowtime becomes shorter, the film thickness is largely reduced in the direction of Y-axis −150 mm (direction separating away from an NH₃ supply port). In the case of the entire plasma, it can be found that such a tendency can not be seen almost at all, and a film is formed equally over the entire surface thereof. FIG. 9 shows the dependence of film forming speed on NH₃-Flowtime while comparing entire plasma and remote plasma with each other. It can be found that in a region where NH₃-Flowtime is relatively short, the film forming speed is faster if entire plasma is used as compared with remote plasma.

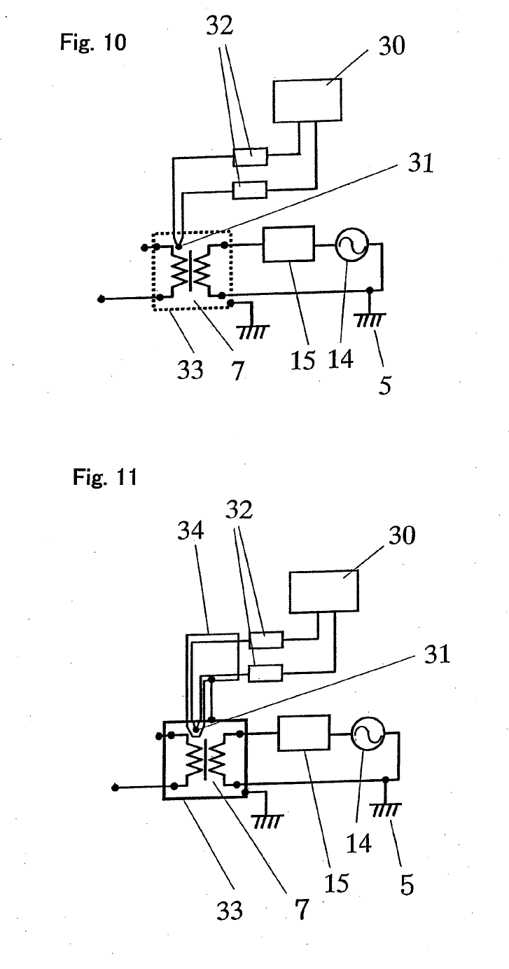

Next, a substrate processing apparatus will be explained with reference to FIGS. 10 to 12. The substrate processing apparatus includes the processing chamber which processes substrates, the pair of electrodes which generates plasma, the high frequency power source, an isolation transformer having a primary side coil which is electrically connected to the high frequency power source and a secondary side coil which is electrically connected to the electrodes, and a thermocouple mounted on the isolation transformer.

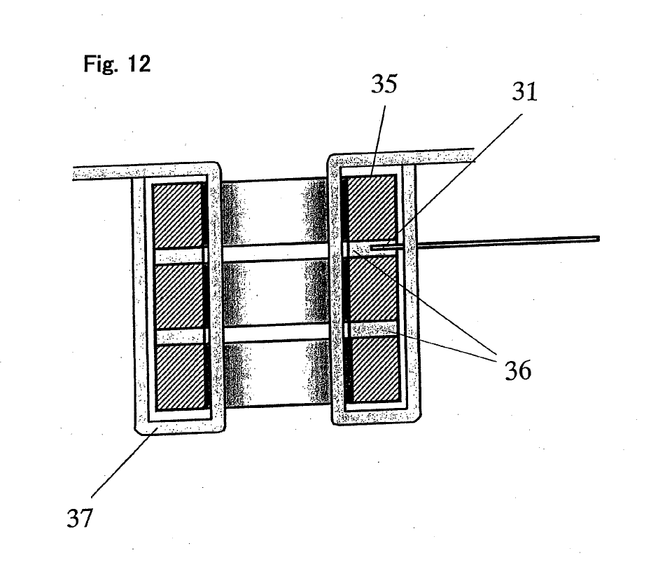

FIG. 10 is a schematic diagram used for explaining one example of a plasma generating circuit used in a processing furnace of a vertical decompression CVD apparatus according to a third embodiment of the present invention. FIG. 11 is a schematic diagram used for explaining another example of the plasma generating circuit used in the processing furnace of the vertical decompression CVD apparatus according to the third embodiment of the invention. FIG. 12 is a schematic diagram used for explaining another example of the plasma generating circuit used in the processing furnace of the vertical decompression CVD apparatus according to the third embodiment of the invention. In the embodiment, the processing furnace is the same as the processing furnace 24 shown in FIGS. 1 and 2.

When the isolation transformer 7 is used as in the first and second embodiments, a ferrite core is used for the isolation transformer 7 for efficiently propagating high frequency electric power of 13.56 [MHz] for example to generate plasma. In such a case, electric characteristics of the core are varied due to mechanical or thermal shock, and the temperature of the core itself rises when RF electric power is applied in some cases. The temperature rise of the core is slightly varied due to variation in core characteristics, but when the characteristics are varied due to the shock, the temperature rises abruptly in some cases.

In the case of the ferrite core, if the temperature exceeds the Curie point, the ferrite core does not function as a transformer, and the transfer machine rises in an accelerative manner and the ferrite core is destroyed.

Therefore, it is considered that a temperature switch (not shown) for detecting the temperature rise of the core is provided in a shielding case (not shown) of the isolation transformer 7. However, if the temperature switch is provided in the shielding case, the temperature switch is provided away from the isolation transformer 7, and the temperature detected by the temperature switch 19 is largely lower than the temperature of the isolation transformer 7.

The temperature detection time is varied due to variation of the peripheral temperature of the shielding case and the heat-transferring path from the isolation transformer 7 to the temperature switch and at the worst, it becomes impossible to prevent the ferrite core constituting the isolation transformer from being destroyed. If RF electric power is supplied in a state in which the ferrite core is damaged, this may rise the temperature of the peripheral parts and this is extremely dangerous.

In this embodiment, in order to appropriately measure the temperature of the isolation transformer, a thermocouple is mounted on the transformer itself, and the temperature rise of the isolation transformer is detected in a state in which the time difference is reduced as small as possible.

Referring to FIG. 10, the isolation transformer 7 is provided with a shielding case 33 for preventing RF electric power from leaking outside. A thermocouple 31 is mounted on the isolation transformer 7, and an electric signal is connected to a temperature measuring device 30 through a noise filter 32. The isolation transformer 7 uses a doughnut-shaped ferrite core so that outer dimensions of the isolation transformer can be reduced.

If a thermocouple having a sheath 34 shown in FIG. 11 is used to suppress the noise influence as small as possible, influence of RF noise when the temperature is measured can be suppressed as small as possible.

FIG. 12 shows a state in which insulation sheets 36 are sandwiched between ferrite cores 35 constituting the isolation transformer 7, and thermocouples 31 are inserted into the insulation sheets 36.

Referring to FIGS. 1, 2, while plasma is generated and substrates 9 in the processing chamber 1 are processed, if the temperature of the isolation transformer 7 measured by the thermocouple 31 (see FIGS. 10 to 12) reaches a preset value, the supply of RF electric power is stopped, and the processing of the substrates 9 is stopped.

If the temperature of the isolation transformer 7 is appropriately measured by the thermocouple 31 mounted on the isolation transformer 7 in this manner, it is possible to avoid a case in which the temperature of the isolation transformer abruptly rises during the processing of the substrates 9 and the apparatus is brought into a dangerous state.

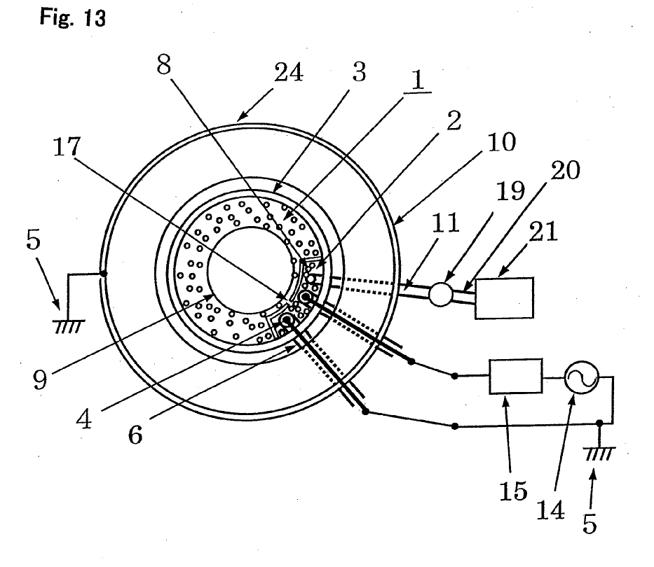

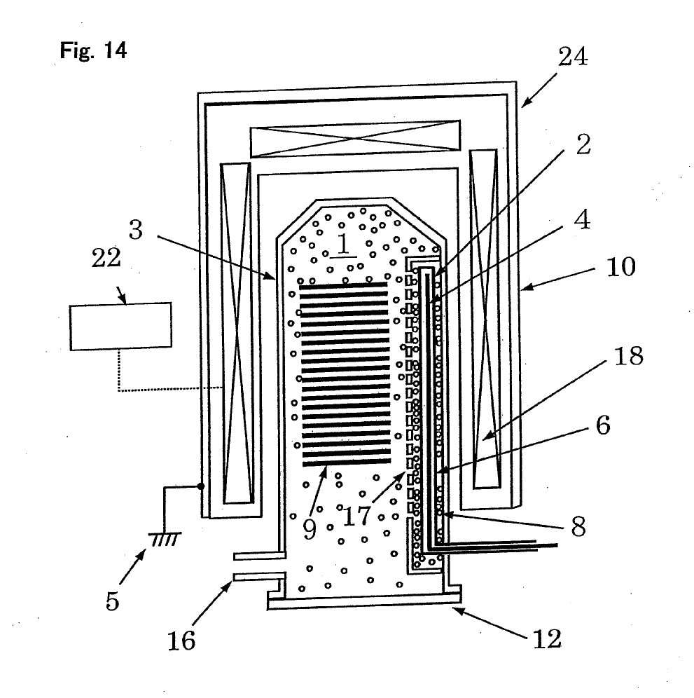

The present inventors conventionally researched a processing furnace of a substrate processing apparatus using remote plasma. FIGS. 13 and 14 show such a processing furnace as a comparative example.

FIGS. 13 and 14 are transverse sectional view and vertical sectional view of a processing furnace 24 of the substrate processing apparatus using remote plasma which was conventionally researched by the present inventors.

The processing chamber 1 is air-tightly formed by a quartz reaction tube 3 and a seal flange 12. The reaction tube 3 is provided at its inner wall side portion with a quartz buffer chamber 2. A pair of electrodes 4 are provided in the buffer chamber 2 for producing plasma 8 by discharge. High frequency electric power supplied from a high frequency power source 14 is supplied to the electrodes 4 through a matching machine 15, and discharge is carried out between the electrodes 4. A heater 18 is provided outside of the reaction tube 3. Substrates 9 in the reaction tube 3 and atmosphere in the processing chamber 1 can be heated to a desired temperature.

The reaction tube 3 is provided at its lower portion with a gas introduction port 11 through which desired gas is introduced into the buffer chamber 2, and an exhaust port 16 through which gas is exhausted from the processing chamber 1. Processing gas introduced from the gas introduction port 11 is brought into plasma state by discharge between the electrodes 4 in the decompressed buffer chamber 2. The processing gas brought into the plasma state is supplied into the processing chamber 1 from a small hole 17 in the buffer chamber 2, and the substrates in the processing chamber 1 are subjected to a desired processing. In order to prevent high frequency electric power generated by the electrodes 4 from leaking outside of the substrate processing apparatus while plasma 8 of processing gas is produced in the buffer chamber 2, a conductive cover 10 connected to the ground 5 is provided outside of the reaction tube 3.

If plasma is produced by the discharge, electrically neutral radical (active species) having relatively long lifetime and small energy, and charged ion having relatively short lifetime and great energy are generated at the same time. In the remote plasma type substrate processing apparatus, plasma is generated only in the buffer chamber 2 (discharge chamber) isolated from the processing chamber, only neutral radical having the relatively long lifetime is supplied to the substrates and processing is carried out (t that time, most of ions having short lifetime are deactivated before they reach the substrates). However, if the high frequency electric power (RF electric power) to be supplied to the electrodes 4 is increased to enhance the substrate processing ability, plasma is produced not only in the buffer chamber 2 (discharge chamber) but also in the entire region in the processing chamber 1. If the high frequency electric power to be supplied to the electrodes 4 is increased, high frequency electric field (RF electric field) generated between the electrodes 4 and the conductive member (e.g., seal flange 12, the heater wire and the cover 10) around the processing chamber 1 is increased, discharge is generated not only in the buffer chamber 2 but also in the entire region in the processing chamber 1 and as a result, plasma is produced in the entire region in the processing chamber 1. If plasma is produced in the vicinity of the substrates, not only the neutral radical (active species) but also high energy ion reaches the substrates. The high energy ion charges up a circuit element which has already been produced on the substrate, the high energy ion destroys the circuit element, and if high energy plasma collides against the substrate, the substrate is physically damaged, and this becomes a cause of hindrance of excellent substrate processing.

The entire disclosure of Japanese Patent Application No. 2003-56772 filed on Mar. 4, 2004 including specification, claims, drawings and abstract are incorporated herein by reference in its entirety.

### INDUSTRIAL APPLICABILITY

As described above, according to the embodiment of the present invention, a substrate can be processed in a state in which plasma is not produced in the vicinity of the substrate. According to the other embodiment, the substrate processing speed can be increased.

As a result, the invention can preferably be utilized especially for a substrate processing apparatus which processes a semiconductor wafer, and for a producing method of device using the substrate processing apparatus.

1. A substrate processing apparatus, comprising:
a processing chamber which processes a substrate or substrates;
a pair of electrodes which generate plasma;
a high frequency power source;
an isolation transformer having a primary side coil which is electrically connected to said high frequency power source and a secondary side coil which is electrically connected to said electrodes; and
a thermocouple mounted to said isolation transformer, wherein
said isolation transformer includes a plurality of ferrite cores stacked, and said thermocouple is inserted into said ferrite cores with said thermocouple being sandwiched between said ferrite cores.

2. A substrate processing apparatus as recited in claim 1, wherein said thermocouple has a sheath.

3. A device producing method which produces a device using said substrate processing apparatus as recited in claim 1.
